(19) United States
(12) Patent Application Publication
(10) Pub. No.: US 2014/0179095 A1
(43) Pub. Date: Jun. 26, 2014

(54) Methods and Systems for Controlling Gate Dielectric Interfaces of MOSFETs

(71) Applicant: INTERMOLECULAR, INC., San Jose, CA (US)

(72) Inventors: Sandip Niyogi, San Jose, CA (US); Sean Barstow, San Jose, CA (US); Chi-I Lang, Cupertino, CA (US)

(73) Assignee: INTERMOLECULAR, INC., San Jose, CA (US)

(21) Appl. No.: 13/725,812

(22) Filed: Dec. 21, 2012

(51) Int. Cl. H01L 21/28

(52) U.S. Cl. CPC H01L 21/28008
USPC 438/591

(57) ABSTRACT

Embodiments provided herein describe methods and systems for forming gate dielectrics for field effect transistors. A substrate including a germanium channel and a germanium oxide layer on a surface of the germanium channel is provided. A metallic layer is deposited on the germanium oxide layer. The metallic layer may be nanocrystalline or amorphous. The deposition of the metallic layer causes the germanium oxide layer to be reduced such that a metal oxide layer is formed adjacent to the germanium channel.

The present invention relates to substrate processing. More particularly, this invention relates to methods and systems for controlling the gate dielectric interface of metal-on-semiconductor field-effect transistors (MOSFETs).

### BACKGROUND OF THE INVENTION

In recent years, the properties of the interfaces between adjacent layers within semiconductor devices have become a more important factor in optimizing performance. This is due, in part, to the ever decreasing size of the features of such devices.

For example, in germanium channel based metal-on-semiconductor field-effect transistors (MOSFETs), aluminum oxide has been shown to provide desirable performance when used as a material for the capping layer. However, the aluminum oxide layer often has a significant number of defects of different types, at the interfaces as well as in the bulk. Additionally, the high temperature processes typically used to deposit the aluminum oxide often causes additional oxidation of the germanium surface and adversely affects any surface passivating functional groups added to the germanium.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a schematic diagram for implementing combinatorial processing and evaluation using primary, secondary, and tertiary screening in accordance with some embodiments of the present invention.

FIG. 2 is a simplified schematic diagram illustrating a general methodology for combinatorial process sequence integration that includes site-isolated processing and/or conventional processing in accordance with some embodiments of the present invention.

FIG. 3 is a simplified schematic diagram illustrating an integrated high productivity combinatorial (HPC) system in accordance with some embodiments of the present invention.

FIG. 4 is a simplified schematic diagram illustrating a processing chamber configured to perform combinatorial processing in accordance with some embodiments of the invention.

FIG. 5 is an isometric view of a showerhead within the processing chamber of FIG. 4 in accordance with some embodiments of the present invention.

FIGS. 6-9 are cross-sectional views of a germanium channel illustrating the formation of a capping layer, a gate dielectric layer, and a gate metal layer thereon

FIG. 10 is a cross-sectional view of a metal-oxide-semiconductor field-effect transistor (MOSFET) in accordance with some embodiments of the present invention.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Embodiments described herein provide methods and systems for forming field-effect transistors (FETs), such as metal-oxide-semiconductor field-effect transistors (MOSFETs). In particular, some embodiments provide methods and systems for forming gate dielectric capping layers for germanium channel based MOSFETs.

In some embodiments, the germanium channel has (e.g., via oxidation) a thin layer of germanium oxide on the exposed surface thereof (as opposed to a relatively thick germanium oxide layer that has been formed or grown over the germanium). A thin, metallic layer (as opposed to a metal oxide layer) is formed over (or on) the germanium channel. The metallic layer may be nanocrystalline or amorphous. The metallic layer reduces the thin layer of germanium oxide and forms a new metal oxide layer over the germanium via, for example, gettering. In some embodiments, the metallic layer has a thickness such that it includes enough material to reduce the entire layer of germanium oxide. As a result, the new metal oxide layer is adjacent to the channel (i.e., germanium).

In some embodiments, the germanium oxide layer has a thickness of not more than 10 Angstroms (Å), and the metallic layer is made of aluminum and has a thickness of, for example, between 3 and 30 Angstroms (Å). The metallic layer may be nanocrystalline or amorphous. In such embodiments, the new metal oxide layer is aluminum oxide, and a portion of the aluminum layer may remain over (or on) the layer of aluminum oxide. The metallic layer may be formed using, for example, plasma enhanced atomic layer deposition (PE-ALD) or ionized physical vapor deposition (iPVD).

The presence of the new metal oxide layer reduces the dipole at the germanium interface because of the new bonds that are formed (e.g., germanium-aluminum-oxygen as opposed to germanium-oxygen-aluminum). This is because the aluminum reduces the germanium oxide to form aluminum oxide and germanium, and any free valency on the germanium surface is compensated by the excess aluminum. Thus, a provision to form germanium-aluminum-oxygen bonds at the interface is created.

Additionally, because the new metal oxide layer is formed by reducing the germanium oxide layer, as opposed to using a high temperature oxidation process, oxidation of and defects on the germanium surface are reduced, if not eliminated.

The processing tool(s) used may allow for combinatorial processing such that the processing parameters may be varied for different regions on the substrate. As such, in accordance with some embodiments, combinatorial processing may be used to produce and evaluate different materials, chemicals, processes, and techniques related to materials, as well as build structures or determine how materials coat, fill or interact with existing structures in order to vary materials, unit processes and/or process sequences across multiple (site-isolated) regions on the substrate(s). These variations may relate to specifications such as temperatures, exposure times, layer thicknesses, chemical compositions, humidity, etc. of the formulations and/or the substrates at various stages of the screening processes described herein. However, it should be noted that in some embodiments, the chemical composition remains the same, while other parameters are varied, and in other embodiments, the chemical composition is varied.

Although the embodiments described herein provide methods and apparatus related to deposition processing, it will be obvious to one skilled in the art that the present invention may be practiced without some or all of these specific details. In other instances, well known process operations have not been described in detail in order not to unnecessarily obscure the present invention.

In the drawings, like reference numerals appearing in different drawings represent similar or same components and perform similar or same functions, unless specifically noted otherwise in the description. Furthermore, as would be appreciated by those skilled in the art, according to common practice, the various features of the drawings discussed herein are not necessarily drawn to scale, and that dimensions of various features, structures, or characteristics of the drawings may be expanded or reduced to more clearly illustrate various implementations of the invention described herein. Semiconductor manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

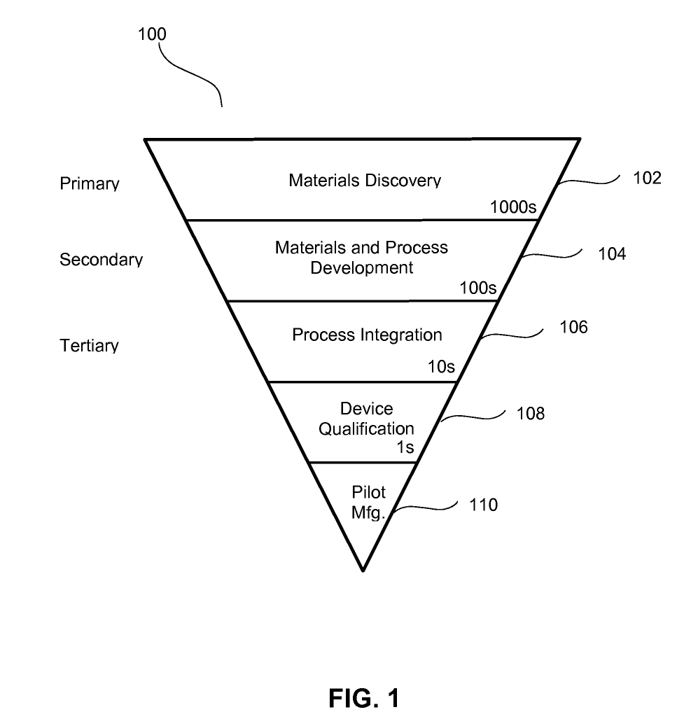

FIG. 1 illustrates a schematic diagram 100 for implementing combinatorial processing and evaluation using primary, secondary, and tertiary screening. The schematic diagram 100 illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage 102. Materials discovery stage 102 is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage 104 may evaluate hundreds of materials (i.e., a magnitude smaller than the primary stage) and may focus on the processes used to deposit or develop those materials. Promising materials and processes are again selected, and advanced to the tertiary screen or process integration stage 106, where tens of materials and/or processes and combinations are evaluated. The tertiary screen or process integration stage 106 may focus on integrating the selected processes and materials with other processes and materials.

The most promising materials and processes from the tertiary screen are advanced to device qualification 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing 110.

The schematic diagram 100 is an example of various techniques that may be used to evaluate and select materials and processes for the development of new materials and processes. The descriptions of primary, secondary, etc. screening and the various stages 102-110 are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007, which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a device. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture, for example, a semiconductor device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor device. For example, such structures may include, but would not be limited to, contact layers, buffer layers, absorber layers, or any other series of layers or unit processes that create an intermediate structure found on semiconductor devices. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

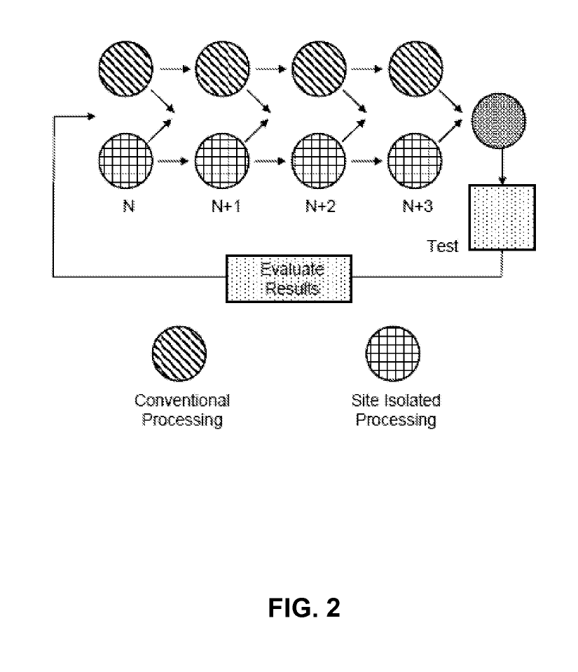

FIG. 2 is a simplified schematic diagram illustrating a general methodology for combinatorial process sequence integration that includes site-isolated processing and/or conventional processing in accordance with some embodiments of the invention. In some embodiments, the substrate is initially processed using conventional process N. In some exemplary embodiments, the substrate is then processed using site-isolated process N+1. During site-isolated processing, an HPC module may be used, such as the HPC module described in U.S. patent application Ser. No. 11/352,077 filed on Feb. 10, 2006. The substrate can then be processed using site-isolated process N+2, and thereafter processed using conventional process N+3. Testing is performed and the results are evaluated. The testing can include physical, chemical, acoustic, magnetic, electrical, optical, etc. tests. From this evaluation, a particular process from the various site-isolated processes (e.g. from steps N+1 and N+2) may be selected and fixed so that additional combinatorial process sequence integration may be performed using site-isolated processing for either process N or N+3. For example, a next process sequence can include processing the substrate using site-isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations, the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor manufacturing may be varied.

As mentioned above, within a region, the process conditions are substantially uniform, in contrast to gradient processing techniques which rely on the inherent non-uniformity of the material deposition. That is, the embodiments described herein locally perform the processing in a conventional manner, e.g., substantially consistent and substantially uniform, while globally over the substrate, the materials, processes, and process sequences may vary. Thus, the testing will find optimums without interference from process variation differences between processes that are meant to be the same. It should be appreciated that a region may be adjacent to another region in some embodiments or the regions may be isolated and, therefore, non-overlapping. When the regions are adjacent, there may be a slight overlap wherein the materials or precise process interactions are not known, however, a portion of the regions, normally at least 50% or more of the area, is uniform and all testing occurs within that region. Further, the potential overlap is only allowed with material of processes that will not adversely affect the result of the tests. Both types of regions are referred to herein as regions or discrete regions.

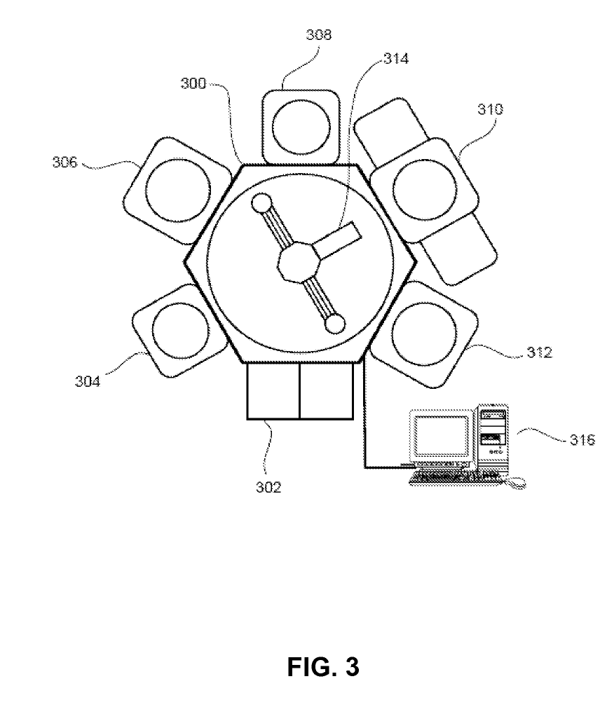

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that the frame 300 may be a unitary frame in accordance with some embodiments. In some embodiments, the environment within the frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. Nos. 11/672,478 and 11/672,473. With HPC system, a plurality of methods may be employed to deposit material upon a substrate employing combinatorial processes.

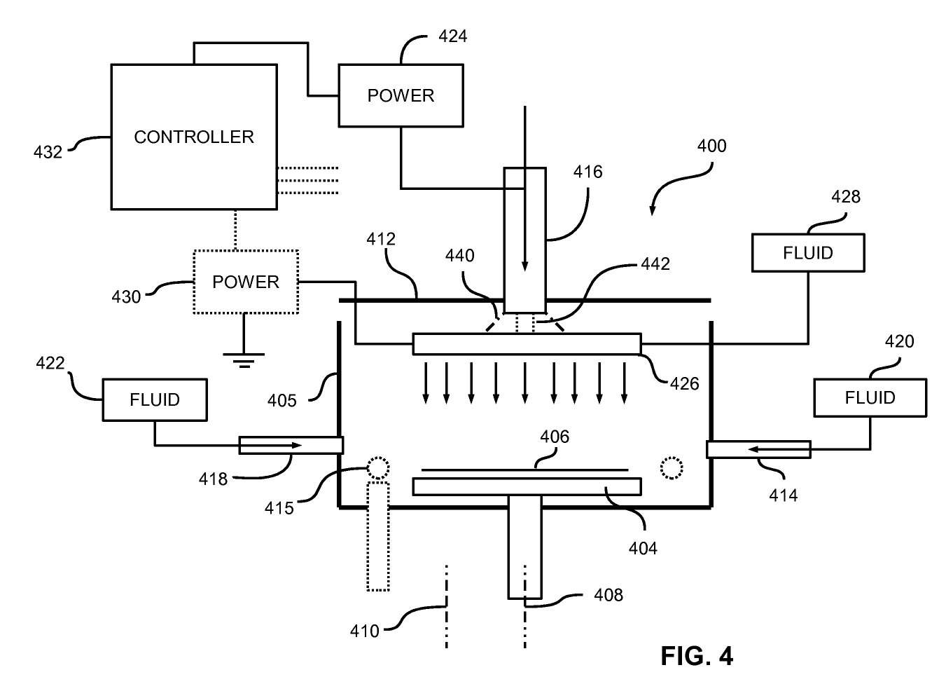

FIG. 4 is a simplified schematic diagram illustrating a processing (e.g., deposition) chamber, or substrate processing tool, 400 configured to perform combinatorial processing in accordance with some embodiments of the invention. The processing chamber 400 is defined by a housing that includes a sidewall 405 and a lid 412 and includes a substrate support 404 which is configured to hold a substrate 406 disposed thereon. The substrate support 404 may be any known substrate support, including but not limited to a vacuum chuck, electrostatic chuck or other known mechanisms. The substrate support 404 is capable of both rotating around its own central axis 408 (referred to as “rotation” axis, which is congruent with a central axis of the substrate 406), and rotating around a second axis 410 (referred to as “revolution” axis). Other substrate supports, such as an XY table, can also be used for site-isolated processing. In addition, the substrate support 404 may move in a vertical direction, i.e., away from or towards lid 412. It should be appreciated that the rotation and movement in the vertical direction may be achieved through known drive mechanisms which include magnetic drives, linear drives, worm screws, lead screws, a differentially pumped rotary feed through drive, etc. A power source 424 provides power to plasma generation source 416. It should be appreciated that power source 424 may output a direct current (DC) power supply, a pulsed DC power supply, or a radio frequency (RF) power supply.

The substrate 406 may be a conventional round 200 mm, 300 mm substrate, or any other larger or smaller substrate/wafer size. In some embodiments, the substrate 406 may be a square, rectangular, or other shaped substrate. One skilled in the art will appreciate that the substrate 406 may be a blanket substrate, a coupon (e.g., partial wafer), or even a patterned substrate having predefined regions. In some embodiments, the substrate 406 may have regions defined through the processing described herein. The term “region” is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

The chamber 400 in FIG. 4 includes a lid 412, through which plasma generation source (or system) 416 extends. Fluid inlets 414 and 418 extend into chamber 400 through sidewalls (or a base) 405 of the chamber 400. Fluid inlet 414 is in fluid communication with fluid source 420, while fluid inlet 418 is in fluid communication with fluid source 422. In some embodiments, fluid inlets 414 and 418 may be in fluid communication with the same fluid source. It should be appreciated that fluid inlets 414 and 418 may extend around a surface of the substrate 406 so that a perimeter of substrate 406 is encompassed by fluid inlets 414 and 418. In some embodiments, fluid inlets 414 and 418 are configured as ring portions surrounding substrate 406.

In some embodiments, fluid inlets 414 and 418 are movable to vertically translate along with the substrate support 404 so that each fluid inlet remains proximate to an edge of substrate 406. For example, the ring portions may be coupled to an appropriate drive such as a worm gear, linear drive, etc., so that the fluid inlets 414 and 418 track the movement of the substrate and substrate support. The plasma generation source 416 is operable to provide a plasma activated species proximate to a surface of substrate 406. The plasma activated species provided by plasma generation source 416 has a non-reactive outer portion 440 surrounding a reactive inner portion 442 in accordance with some embodiments. It should be further appreciated that plasma generation source 416 may be a commercially available inductively coupled radio frequency (RF) plasma generation source. It should be appreciated that a plasma activated species refers to the reactive atomic and molecular radicals converted from the precursor gas through interaction with the plasma. It should be further appreciated that the plasma also consists of non-charged species (e.g., radicals) and charged species (e.g., ions and electrons). Further, it should be understood that the plasma generation source (or system) 416 may include means for generating multiple types of plasma simultaneously.

The embodiments illustrated in FIG. 4 provide for independent control of the plasma and the feedstock of the film to be deposited. Thus, the plasma activated species are provided by the plasma generation source 416 located at the top of the chamber 400, while the film feedstock is delivered through the chamber base to a ring disposed around the wafer surface. Alternatively, the film feedstock may be delivered through the bottom of the chamber to distribution ring 415 above or proximate to the substrate surface. In some embodiments, the distribution ring 415 is coupled to the substrate support 404 so that the ring vertically translates with the substrate support. It should be appreciated that the feedstock interacts with the plasma proximate to a surface of substrate 406 so that site-isolated processing may be performed on different regions of substrate 406. It should be further appreciated that the chamber 400 may be a vapor deposition chamber that includes chemical vapor deposition chambers and atomic layer deposition chambers.

In some embodiments, a plasma provided through the plasma generation source 416 includes a hydrogen, nitrogen, argon, oxygen, ammonia, nitrogen trifluoride, helium, or a combination thereof, based plasma referred to as a first precursor. The film feedstock provided by fluid inlets 414 and 418 may be any suitable feedstock for the desired deposition layer and may be referred to as a second precursor. Thus, for some embodiments described herein, the first precursor carries the plasma activated species and activates the second precursor proximate to the substrate surface at a specific site or region. In some embodiments, the film feedstock may be methane (CH₄) so that an amorphous carbon layer is deposited on the region of the surface of substrate 406. With regard to an atomic layer deposition chamber (ALD), a pulsed exposure to oxygen radicals generated when oxygen gas is precursor 1, can be utilized to complete the oxidation of the metal source to avoid defects and vacancies in ALD films. In some embodiments, in order to generate a profile of nitrogen and oxygen in an ALD deposited aluminum film, the ALD layer can be exposed to a nitrogen/oxygen plasma at regular intervals during film deposition. However, as described below, in accordance with some embodiments of the present invention, only one precursor (i.e., the first) is utilized, and a second precursor is not introduced into the chamber 400.

Still referring to FIG. 4, the chamber 400 also includes a showerhead 426 suspended between the plasma generation source 416 and the substrate 406. Although not shown, the showerhead 426 may be vertically translatable (i.e., movable) within the chamber 400. An additional fluid source 428 is provided and coupled to (i.e., in fluid communication with) the showerhead 426. As described below, fluid source 428 may provide, for example, an inert gas to the showerhead during processing. Additionally, in some embodiments, the showerhead 426 is grounded as shown in FIG. 4. However, in other embodiments, a power supply (and controller) 430 may also be provided to control and modulate the charge on the showerhead 426.

The chamber 400 also includes a controller (or control sub-system) 432 which is in operable communication with the other components of the chamber 400, such as fluid sources 420, 422, and 428, power supply 424, etc. (not all connections are shown for clarity). The controller 432 includes, for example, a processor and memory, such as random access memory (RAM) and a hard disk drive. The controller 432 is configured to control the operation of the chamber 400 to perform the methods and processes described herein.

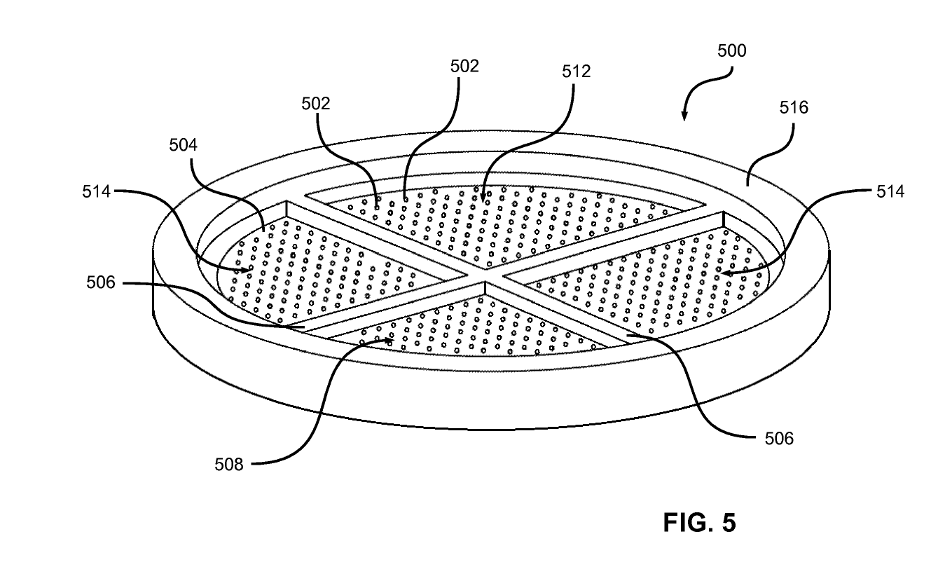

FIG. 5 illustrates a showerhead 500 (e.g., showerhead 426 in FIG. 4) according to some embodiments of the present invention. The showerhead 500 is substantially circular and has a diameter of, for example, approximately 200 or 300 millimeters. A plurality of injection ports (or openings) 502 extend through a bottom portion (or piece) 504 of the showerhead 500. Although not shown in detail, each of the injection ports 502 may have a diameter that varies as it extend through the bottom portion 504, with a larger diameter near an upper surface of the bottom portion 504.

A fluid separation mechanism 506 extends upwards from the bottom portion 504 and includes several substantially linear member that divide the injection ports 502 into four regions, or quadrants, 508, 510, 512, and 514. The distance that fluid separation mechanism 506 extends from the main body is dependent upon the specific design parameters and may vary in different embodiments. However, in at least some embodiments, the fluid separation mechanism 506 provides sufficient separation to minimize, if not prevent, fluids from diffusing between adjacent quadrants 114-117. In some embodiments, quadrants 508, 510, 512, and 514 correspond to similarly shaped, site-isolated regions on the substrate 406 (FIG. 4). As such, the showerhead 500 may allow for combinatorial processing of such regions on the substrate 406. Additionally, a fluid trap ring 516 extends upwards from around a periphery of the bottom portion 504 and may assist in containing fluid within the showerhead 500. The showerhead 500 may be formed from any known suitably inert materials, such as stainless steel, aluminum, anodized aluminum, nickel, ceramics and the like.

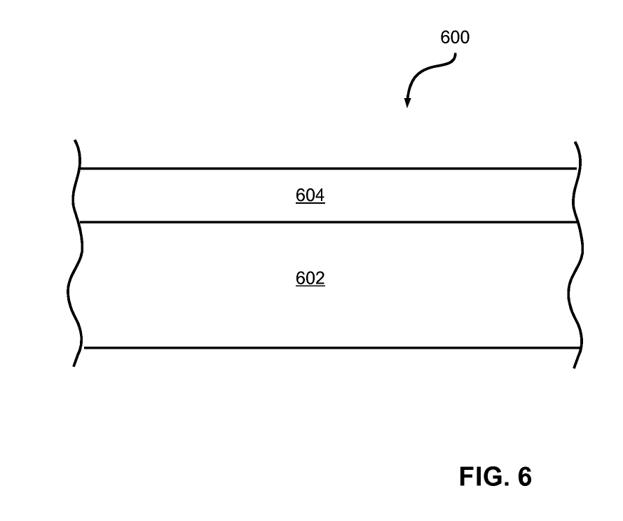

FIGS. 6-10 illustrate a method for forming a FET, in particular forming a gate dielectric for a FET, according to some embodiments of the present invention. Referring to FIG. 6, a substrate 600 is illustrated. The substrate 600 includes a germanium channel (or layer) 602 and a germanium oxide layer 604. The germanium channel 602 has a thickness of, for example, between 5 and 10 nanometers (nm) (not shown). Although not shown in FIGS. 6-9, it should be understood that in some embodiments the germanium channel 602 is formed on a silicon substrate. The germanium oxide layer 604 is formed over (or on) an upper surface of the germanium channel 602. In some embodiments, the germanium oxide layer 604 is formed via oxidation of the germanium channel 602, such as by exposure to the atmosphere (e.g., oxidation). As such, in some embodiments, the germanium oxide layer 604 is relatively thin. For example, in some embodiments, the germanium oxide layer 604 may have a thickness of, for example, between 10 and 15 Å. It should be noted that, in at least some embodiments, no processing is performed to increase the thickness of, or “grow,” the germanium oxide layer 604 prior to the subsequent processing steps described below.

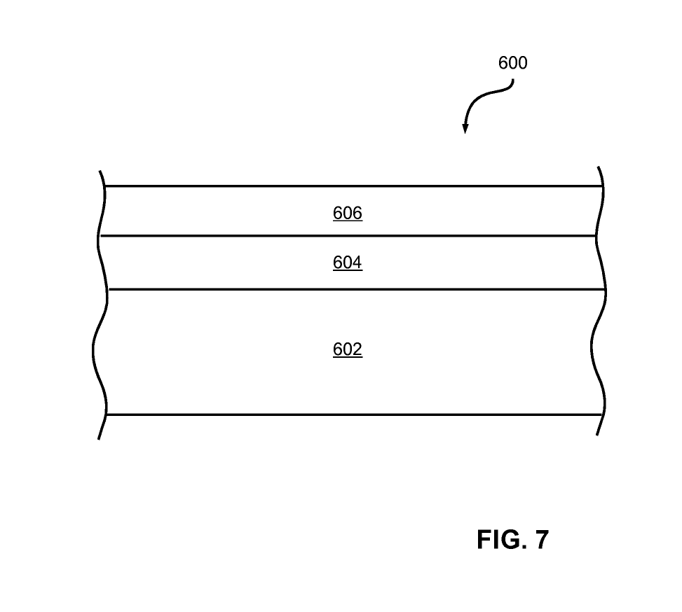

Next, as shown in FIG. 7, a metallic layer 604 is deposited over the germanium oxide layer 604. The metallic layer may be nanocrystalline or amorphous. In some embodiments, the thickness of the metallic layer 604 is not less (i.e., greater than or equal to) the thickness of the germanium oxide layer 604. For example, the metallic layer 606 may have a thickness of, for example, between 5 and 30 Å. In some embodiments, the metallic layer 604 is made of aluminum, however, in other embodiments, hafnium or titanium may be used.

The metallic layer 604 may be deposited using, for example, PE-ALD or iPVD. In embodiments using PE-ALD, the processing chamber 400 shown in FIG. 4 may be utilized with, for example, hydrogen plasma as the first precursor and trimethylaluminum (TMA) as the second precursor, or feedstock. However, prior to the deposition of the metallic layer 604, the processing chamber 400 may perform a “surface treatment” process on the germanium oxide layer 604.

An exemplary surface treatment includes exposing the germanium oxide layer 604 to only, or substantially only, the radical (or non-charged) species of a plasma. In some embodiments, the radical species includes fluorine radicals. In such embodiments, a plasma (e.g., nitrogen trifluoride plasma) is generated by the plasma generation source 416. The plasma is discharged into the chamber 400 and through the showerhead 426. In some embodiments, at least some, if not all, of the charged species (e.g., ions and electrons) of the plasma are collected in or by the showerhead 426 such that only (or substantially only) the radical species of the plasma is allowed to flow from the injection ports 502 (FIG. 5) and onto the substrate 406. It should be noted that in such a treatment only one precursor (i.e., the plasma) is used, as a second precursor is not introduced into the chamber 400.

Referring again to FIG. 4, the collecting of the charged species by the showerhead 426 may be facilitated by electrically grounding the showerhead, which may cause virtually all of the charged species to be collected by the showerhead 426. However, in other embodiments, the charge on the showerhead 426 may be modulated by power supply 430, which may allow some of the charged species to pass through the showerhead 426 and onto the substrate 406. Additionally, in order to extend the “lifetime” of the radical species, an inert gas, such as argon, may be introduced into the showerhead 426 by fluid source 428 to reduce collisions with the charged species and allow for a greater number of radical species to be flowed onto the substrate 406.

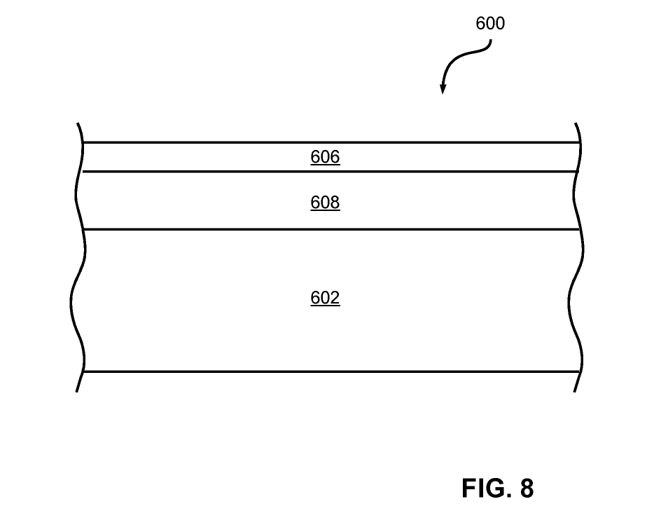

Referring now to FIGS. 7 and 8, after the surface treatment and the deposition of the metallic layer 606, due to gettering, the germanium oxide layer 604 may be reduced (i.e., oxygen reduction) and at least a portion of the metallic layer 606 may be oxidized. This reduction/oxidation may be facilitated by the surface treatment and the reactive nature of the metallic layer 606.

Specifically referring to FIG. 8, as a result of the reduction/oxidation, the germanium oxide layer 604 may no longer be present as the material thereof is now at least partially added to the germanium channel 602 and the thickness of the metallic layer 606 may be at least partially reduced. Additionally, a metal oxide (or capping) layer 608 may be formed between the germanium channel 602 and the (remainder) of the metallic layer 606. However, it should be understood that in some embodiments, the entire metallic layer 606 may be oxidized, such that none of the metallic layer 606 remains over the metal oxide layer 608.

In embodiments utilizing aluminum for the metallic layer 606, the metal oxide layer 608 may be made of aluminum oxide. The metal oxide layer may, for example, have a thickness similar to that of the germanium oxide layer 604 (e.g., 5-10 Å).

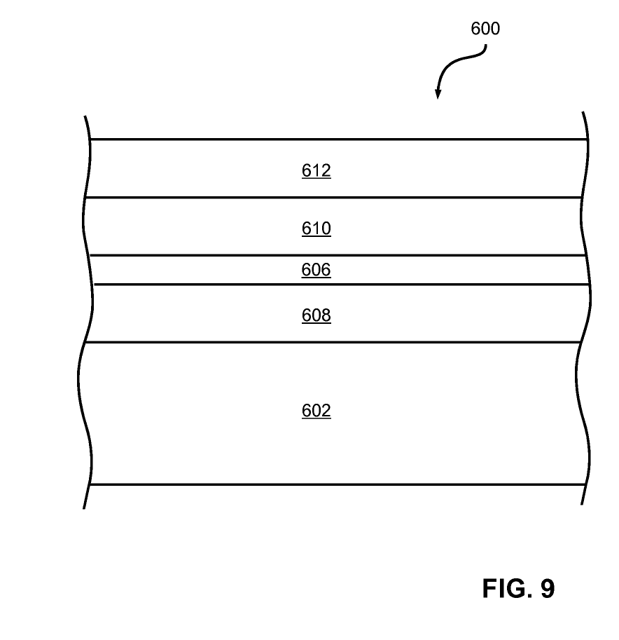

Referring now to FIG. 9, a gate dielectric layer 610 and a gate metal layer 612 are then formed over the metal oxide layer 608 (and/or the remainder of the metallic layer 606). The gate dielectric layer 610 may, for example, be made of hafnium oxide, zirconium oxide, or a combination thereof and have a thickness of between 0.5 and 2.0 nm. The gate metal layer 612 may, for example, be made of titanium, titanium nitride, nickel, or a combination thereof and have a thickness of between 1.0 and 10 nm. The gate dielectric layer 610 and the gate metal layer 612 may be formed using, for example, ALD.

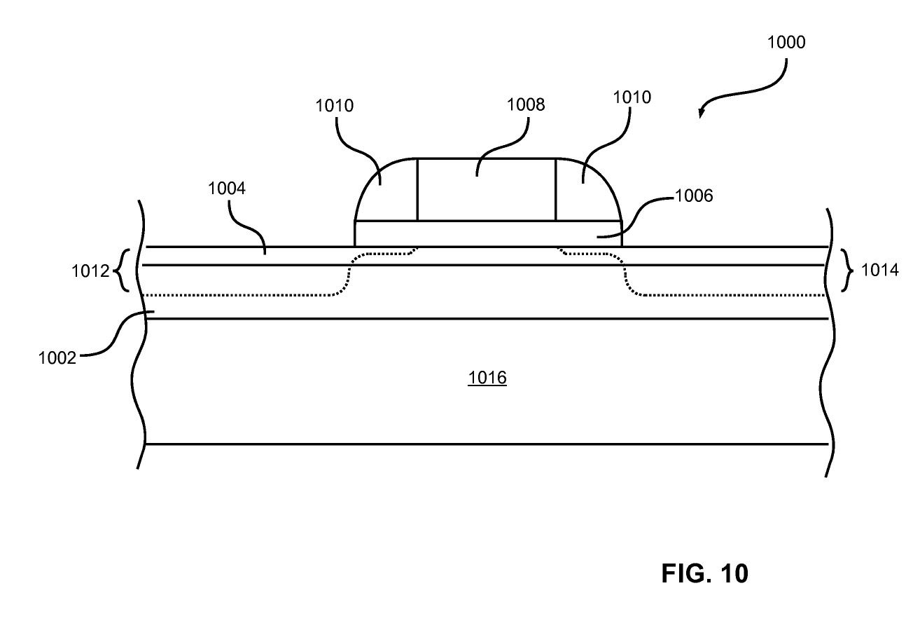

Referring now to FIG. 10, after the formation of the gate dielectric layer 610 and the gate metal layer 612, additionally processing steps may be performed to complete/form a germanium channel MOSFET 1000. In some embodiments, the MOSFET 1000 includes a germanium channel (or layer) 1002, a capping layer 1004, a gate dielectric (or gate dielectric layer) 1006, a gate metal (or gate metal layer) 1008, which may take the form of the similarly named components described above, along with spacers 1010 and respective source and drain regions 1012 and 1014. The spacers 1010 may be made of silicon dioxide and may be used to, for example, mask the remainder of the device and define the source and drain regions 1012 and 1014, which may be formed using any known implantation process. As also shown in FIG. 10, in some embodiments, the germanium channel 1002 may be formed on a silicon substrate 1016.

Implementations of the invention may be described as including a particular feature, structure, or characteristic, but every aspect or implementation may not necessarily include the particular feature, structure, or characteristic. Further, when a particular feature, structure, or characteristic is described in connection with an aspect or implementation, it will be understood that such feature, structure, or characteristic may be included in connection with other implementations, whether or not explicitly described. Thus, various changes and modifications may be made to the provided description without departing from the scope or spirit of the invention. As such, the specification and drawings should be regarded as exemplary only, and the scope of the invention to be determined solely by the appended claims.

Thus, in some embodiments, a method for forming a gate dielectric for a field effect transistor is provided. A substrate including a germanium channel and a germanium oxide layer on a surface of the germanium channel is provided. A metallic layer is deposited on the germanium oxide layer. The metallic layer may be nanocrystalline or amorphous. The deposition of the metallic layer causes the germanium oxide layer to be reduced such that a metal oxide layer is formed adjacent to the germanium channel.

In some embodiments, a method for forming a gate dielectric for a field effect transistor is provided. A substrate including a germanium channel and a germanium oxide layer on a surface of the germanium channel is provided. The germanium oxide layer has a first thickness. A metallic layer having a second thickness is deposited on the germanium oxide layer. The metallic layer may be nanocrystalline or amorphous. The second thickness is greater than the first thickness. The deposition of the metallic layer causes the germanium oxide layer to be reduced such that a metal oxide layer is formed adjacent to the germanium channel. The metal oxide layer does not comprise germanium.

In some embodiments, a method for forming a gate dielectric for a metal-oxide-semiconductor field effect transistor is provided. A substrate including a germanium channel and a germanium oxide layer on a surface of the germanium channel is provided. An aluminum layer is deposited on the germanium oxide layer. The aluminum layer may be nanocrystalline or amorphous. The deposition of the aluminum layer causes the germanium oxide layer to be reduced such that an aluminum oxide layer is formed adjacent to the germanium channel. A gate dielectric layer is formed over the metal oxide layer. A gate metal layer is formed over the dielectric layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method for forming a gate dielectric for a field effect transistor, the method comprising:
providing a substrate comprising a germanium channel and a germanium oxide layer on a surface of the germanium channel; and
depositing a metallic layer on the germanium oxide layer, the metallic layer causing the germanium oxide layer to be reduced such that a metal oxide layer is formed adjacent to the germanium channel.

2. The method of claim 1, wherein the metal oxide layer comprises the metal of the metallic layer.

3. The method of claim 1, wherein the metal oxide layer does not comprise germanium.

4. The method of claim 1, wherein a thickness of the metallic layer is greater than a thickness of the germanium oxide layer.

5. The method of claim 1, wherein the metallic layer comprises aluminum.

6. The method of claim 4, wherein the thickness of the metallic layer is between 3 and 30 Angstroms (Å).

7. The method of claim 5, wherein the metallic layer is formed using plasma enhanced atomic layer deposition (PE-ALD) or ionized physical vapor deposition (iPVD).

8. The method of claim 6, wherein the metallic layer is formed using PE-ALD and further comprising exposing the germanium oxide layer to hydrogen radicals before the forming of the metallic layer.

9. The method of claim 1, further comprising forming a gate dielectric layer over the metal oxide layer.

10. The method of claim 9, further comprising forming a gate metal layer over the gate dielectric layer.

11. A method for forming a gate dielectric for a field effect transistor, the method comprising:
providing a substrate comprising a germanium channel and a germanium oxide layer on a surface of the germanium channel, the germanium oxide layer having a first thickness; and
depositing a metallic layer having a second thickness on the germanium oxide layer, the second thickness being greater than the first thickness, the metallic layer causing the germanium oxide layer to be reduced such that a metal oxide layer is formed adjacent to the germanium channel, wherein the metal oxide layer does not comprise germanium.

12. The method of claim 11, further comprising:
forming a gate dielectric layer over the metal oxide layer; and
forming a gate metal layer over the gate dielectric layer.

13. The method of claim 12, wherein the second thickness is less than 30 Å.

14. The method of claim 13, wherein the metallic layer is formed using PE-ALD, and further comprising exposing the germanium oxide layer to hydrogen radicals before the forming of the metallic layer.

15. The method of claim 14, wherein the metallic layer comprises aluminum.

16. A method for forming a gate dielectric for a metal-oxide-semiconductor field effect transistor, the method comprising:
providing a substrate comprising a germanium channel and a germanium oxide layer on a surface of the germanium channel;
depositing an aluminum layer on the germanium oxide layer, the deposition of the aluminum layer causing the germanium oxide layer to be reduced such that an aluminum oxide layer is formed adjacent to the germanium channel;
forming a gate dielectric layer over the metal oxide layer; and
forming a gate metal layer over the gate dielectric layer.

17. The method of claim 16, wherein a thickness of the aluminum layer is greater than a thickness of the germanium oxide layer, and the thickness of the aluminum layer is less than 30 Å.

18. The method of claim 17, further comprising exposing the germanium oxide layer to hydrogen radicals before the forming of the aluminum layer.

19. The method of claim 17, wherein the gate dielectric layer comprises hafnium oxide or zirconium oxide.

20. The method of claim 19, wherein the gate metal layer comprises titanium, nickel, or a combination thereof.
